(19) United States
(12) Patent Application Publication
(10) Pub. No.: US 2025/0129212 A1
(43) Pub. Date: Apr. 24, 2025

(54) POROUS FILM AND COPPER CLAD LAMINATE

(71) Applicant: INDUSTRIAL TECHNOLOGY RESEARCH INSTITUTE, Hsinchu (TW)

(72) Inventors: Li-Ting HUANG, New Taipei City (TW); Tzong-Ming LEE, Zhubei City (TW)

(73) Assignee: INDUSTRIAL TECHNOLOGY RESEARCH INSTITUTE, Hsinchu (TW)

(21) Appl. No.: 18/605,941

(22) Filed: Mar. 15, 2024

(30) Foreign Application Priority Data
Oct. 24, 2023 (CN) 202311384075.X
Oct. 24, 2023 (TW) 112140677

(51) Int. Cl. C08G 73/10; C08J 9/28; H05K 1/03

(52) U.S. Cl. CPC C08G 73/105; C08J 9/28; C08J 2205/026; C08J 2205/044; C08J 2379/08; H05K 1/0353; H05K 2201/0116; H05K 2201/0355

(57) ABSTRACT

A porous film is formed by reacting polyamic acid and multi-isocyanate, and the polyamic acid is formed by reacting 1 to 20 parts by mole of (a1) first diamine having a hydroxyl group, 80 to 99 parts by mole of (a2) second diamine without any hydroxyl group, and 100 parts by mole of (b) dianhydride. The multi-isocyanate and (b) dianhydride have a molar ratio of 0.25:100 to 20:100. The porous film has an average pore size of 500 nm to 2000 nm.

### CROSS REFERENCE TO RELATED APPLICATIONS

The present application is based on, and claims priority from, Taiwan Application Serial No. 112140677, filed on Oct. 24, 2023, and China Application Serial No. 202311384075.X, filed on Oct. 24, 2023, the disclosure of which is hereby incorporated by reference herein in its entirety.

### TECHNICAL FIELD

The technical field relates to porous film and copper clad laminate.

### BACKGROUND

In terms of the substrate materials in printed circuit boards used in network-related equipment such as servers and routers, not only are high-density substrate materials required, but so are multi-layered substrate materials. The substrate materials used in printed circuit boards need high reflow heat resistance, through-hole reliability, and low transmission loss.

With the advancement of wireless transmission products and high-frequency transmission technology, it is difficult to use existing substrate resin materials to satisfy advanced applications. For example, poor wire adhesion is prone to occur after a solvent cleaning when making printed circuit boards. Also, the melting point and glass transition temperature (Tg) of the substrate resin are too close to withstand soldering operations above 250° C. In addition, the dielectric properties of the substrate resin cannot meet the requirements of ultra-low dielectric constant (Dk<2.0).

As such, the development of new materials that have excellent dielectric properties and that have other properties required for use in printed circuit boards (such as high heat resistance, high dimensional stability, and high mechanical strength) is urgently needed at this stage, so that printed circuit board material suppliers can apply such materials toward the manufacture of high-frequency printed circuit boards.

### SUMMARY

One embodiment of the disclosure provides a porous film, being formed by reacting polyamic acid and multi-isocyanate, and the polyamic acid is formed by reacting 1 to 20 parts by mole of (a1) first diamine having a hydroxyl group; 80 to 99 parts by mole of (a2) second diamine without any hydroxyl group; and 100 parts by mole of (b) dianhydride, wherein the multi-isocyanate and (b) dianhydride have a molar ratio of 0.25:100 to 20:100, and wherein the porous film has an average pore size of 500 nm to 2000 nm.

One embodiment of the disclosure provides a copper clad laminate, including the described porous film interposed between two copper foils; and two thermosetting ethylene copolymer resin layers being respectively between the porous film and the copper foils.

A detailed description is given in the following embodiments.

### DETAILED DESCRIPTION

In the following detailed description, for purposes of explanation, numerous specific details are set forth in order to provide a thorough understanding of the disclosed embodiments. It will be apparent, however, that one or more embodiments may be practiced without these specific details.

One embodiment of the disclosure provides a porous film, being formed by reacting polyamic acid and multi-isocyanate, and the polyamic acid is formed by reacting 1 to 20 parts by mole of (a1) first diamine having a hydroxyl group, 80 to 99 parts by mole of (a2) second diamine without any hydroxyl group, and 100 parts by mole of (b) dianhydride. If (a1) first diamine amount is too low, the network density and the porous skeleton strength of the formed porous film may be insufficient. An overly low porous skeleton strength may result in poor mechanical strength, thereby limiting the use of the material when subjected to mechanical stress. If (a1) first diamine amount is too high, the network density of the formed porous film will be easily too high, such that the material will be difficult to process due to its high rigidity and brittleness.

For example, if 2,2-bis(3-amino-4-hydroxyphenyl) hexafluoropropane (6FAP) is selected for (a1) first diamine, a combination of 4,4′-diamino-2,2′-dimethylbiphenyl (DMB) and 4,4′-oxydianiline (ODA) is selected for (a2) second diamine, and a combination of 3,3′,4,4′-biphenyltetracarboxylic dianhydride (BPDA) and pyromellitic dianhydride (PMDA) is selected for (b) dianhydride, the polyamic acid has a chemical structure of

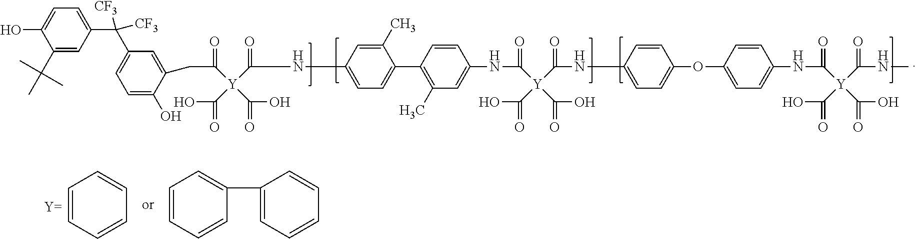

In the above chemical structure, the side chain of polyamic acid has hydroxyl groups. The subsequently added multi-isocyanate may react and crosslink with the hydroxyl groups. The amino groups and the carboxylic acid groups in the backbone of the polymer will ring-close to form the polyimide porous film. It should be understood that the above (a1) first diamine, (a2) second diamine, and (b) dianhydride are merely examples and are not intended to be limiting. The other (a1) first diamine, (a2) second diamine, and (b) dianhydride also belong to the field of the disclosure.

In some embodiments, the multi-isocyanate and (b) dianhydride have a molar ratio of 0.25:100 to 20:100, or 0.5:100 to 20:100. If the multi-isocyanate amount is too low, the formed network density will be insufficient, the material will easily expand or contract as the temperature changed (e.g. increasing the coefficient of thermal expansion). If the multi-isocyanate amount is too high, the formed network density and the ratio of bondings prone to high temperature cleavage will be too high, and the thermal resistance of the material will be reduced. An overly high network density may increase the hardness and the brittleness of the material and decrease the porosity of the material.

In some embodiments, the porous film has an average pore size of 500 nm to 2000 nm. If the average pore size of the porous film is too small, the porous film will easily deform when heated, thereby causing the pores collapse. In addition, the porous skeleton strength cannot resist the surface tension and the capillary force during the drying process, such that the porous film cannot be prepared by ambient pressure drying method. If the average pore size of the porous film is too large, the dielectric constant and the dissipation factor of the material will be increased.

In some embodiments, (a1) first diamine has a chemical structure of

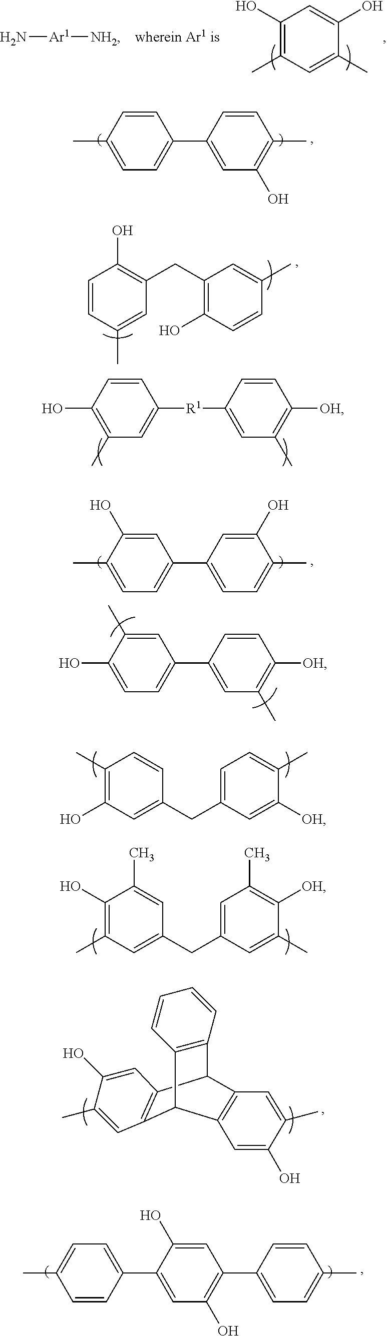

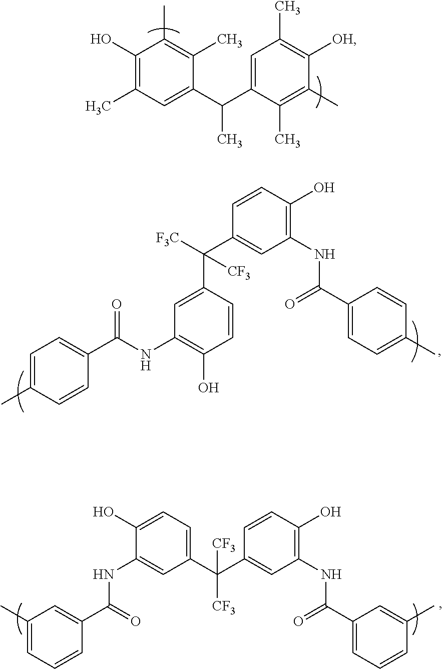

or a combination thereof, wherein R¹ is —SO₂—, —C(CH₃)₂—, or —C(CF₃)₂—.

In some embodiments, (a2) second diamine has a chemical structure of H₂N—Ar²—NH₂, wherein Ar² is —(CH₂)ₙ—,

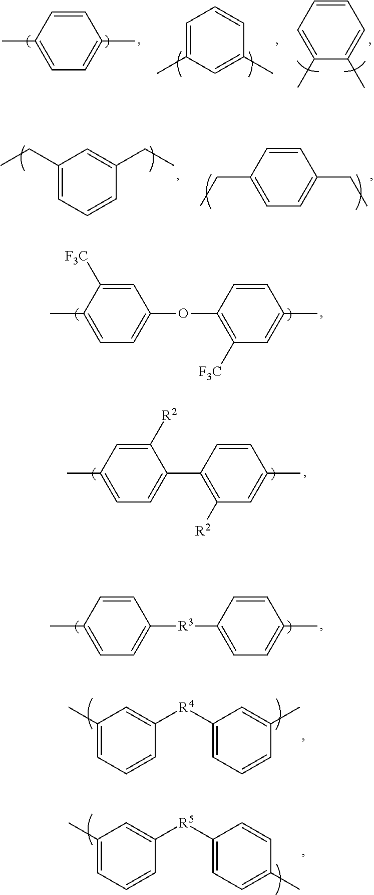

or a combination thereof, wherein n=1 to 10, wherein R² is —H, —CH₃, —CF₃, or —OCH₃, wherein R³ is —O—, —S—, —CH₂—, —CO—, —SO₂—, —CONH—, —C(CH₃)₂—, —C(CF₃)₂—, —O(CH₂)₃O—,

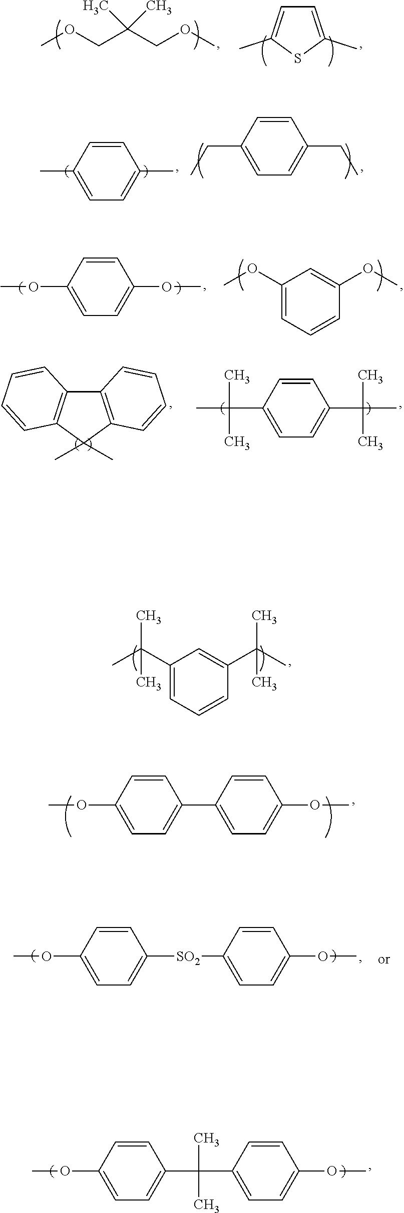

wherein R⁴ is —O—, —CH₂—, —CO—, —SO₂—,

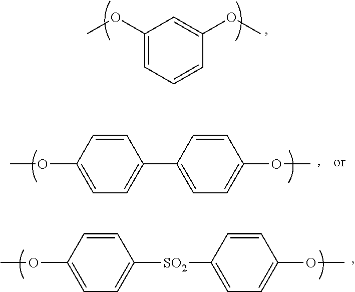

and wherein R⁵ is —O—, —CH₂—, —CONH—,

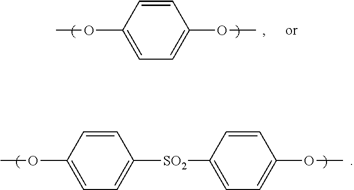

In some embodiments, (b) dianhydride has a chemical structure of

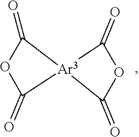

wherein Ar³ is

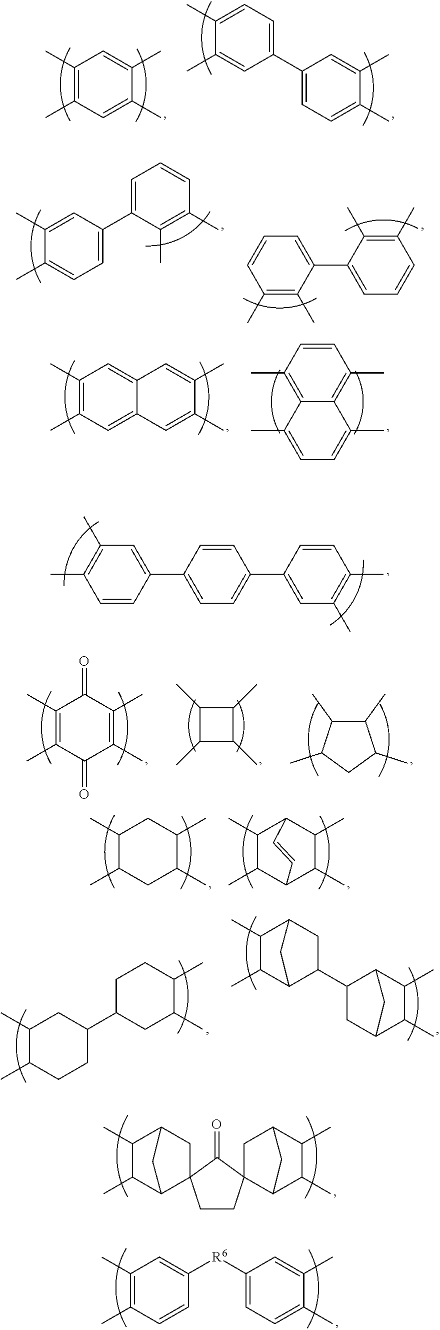

or a combination thereof, wherein R⁶ is —O—, —S—, —C≡C—, —CO—, —COO—, —SO₂—, —C(CF₃)₂—, —COO(CH₂)₂OCO—,

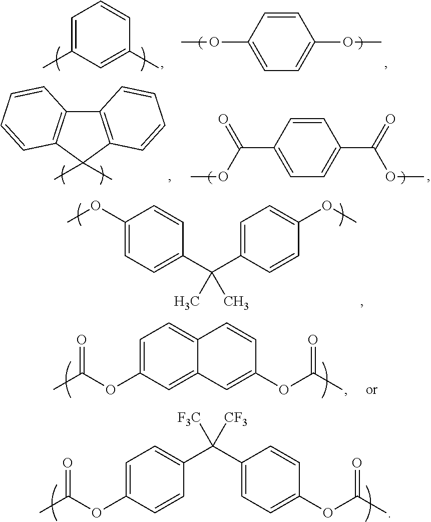

In some embodiments, the multi-isocyanate is diisocyanate, triisocyanate, tetraisocyanate, or a combination thereof. The diisocyanate has a chemical structure of OCN—R⁷—NCO, wherein R⁷ is —(CH₂)₅—, —(CH₂)₆—,

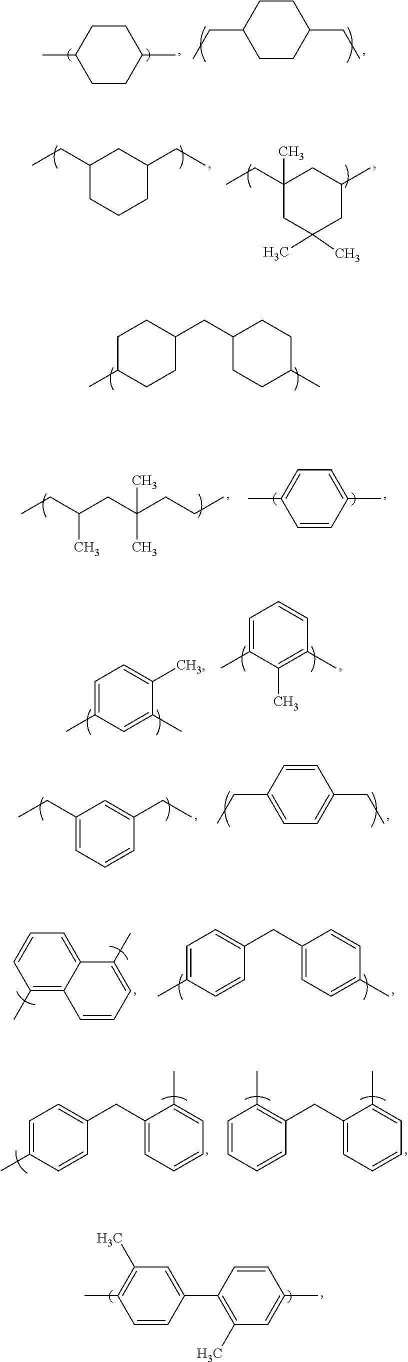

or a combination thereof. The triisocyanate has a chemical structure of

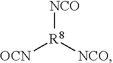

wherein R⁸ is

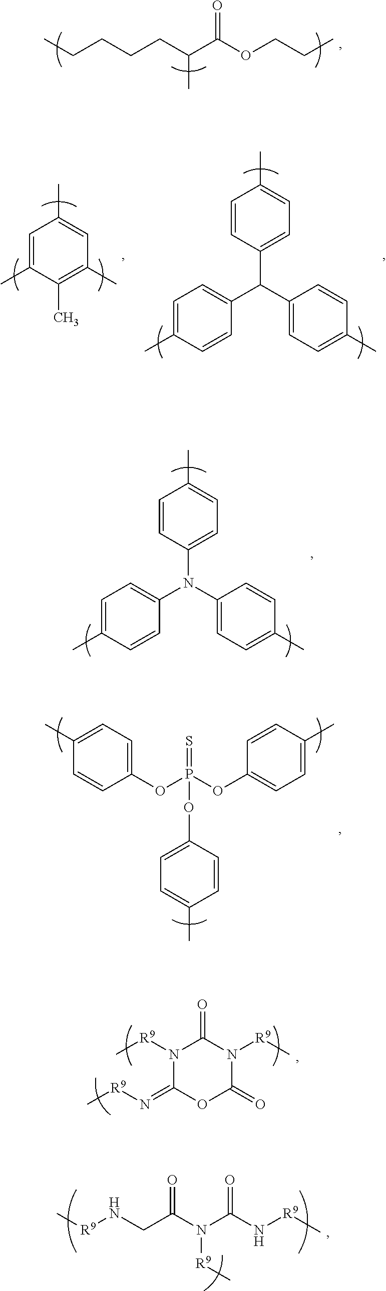

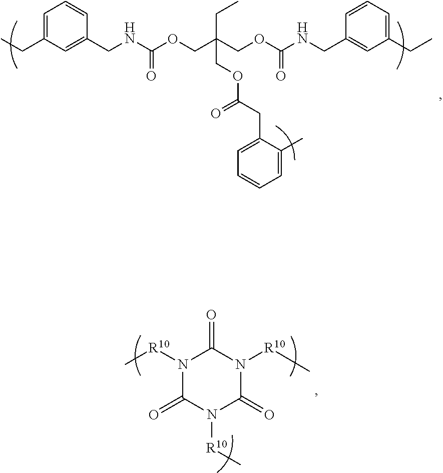

or a combination thereof, wherein R⁹ is —(CH₂)₆—, and each of R¹⁰ is independently —(CH₂)₆—,

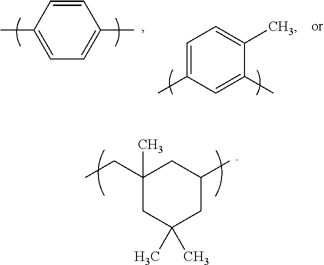

The tetraisocyanate is tetraisocyanatosilane, 4,4′-benzylidenebis(6-methyl-m-phenylene) tetraisocyanate, or a combination thereof.

In some embodiments, the porous film has a dielectric constant of <1.4 and a dissipation factor of <0.02 at 10 GHz.

One embodiment of the disclosure provides a copper clad laminate, including the described porous film interposed between two copper foils, and two thermosetting ethylene copolymer resin layers being respectively between the porous film and the copper foils.

In some embodiments, the thermosetting ethylene copolymer resin layers include di-block or tri-block hydrogenated styrene elastomer resin or hydrogenated (styrene-isoprene) copolymer.

In some embodiments, the copper clad laminate has a dielectric constant of <2.0 and a dissipation factor of <0.01 at 10 GHz.

Below, exemplary embodiments will be described in detail so as to be easily realized by a person having ordinary knowledge in the art. The inventive concept may be embodied in various forms without being limited to the exemplary embodiments set forth herein.

### EXAMPLES

In following Examples, the density of the porous film was measured according to ASTM D792. The average pore size of the porous film was measured by scanning electron microscope (SEM) to analyze the microstructure of the material. The porosity of the porous film was measured according to ASTM D6226. The thermal decomposition temperature (T_{d} 5%) was measured according to ASTM E2550. The coefficient of thermal expansion of the porous film was measured according to ASTM E831. The compressive modulus of the porous film was measured according to ASTM D695-10. The compressive stress at 10% strain of the porous film was measured according to ASTM D695-10. The dielectric constant and the dissipation factor at 10 GHz of the porous film were measured according to ASTM D2520. The volume contraction ratio (%) at 300° C. for 2 hours of the porous film was calculated from the volume change. The volume change is obtained by a digital caliper to measure the length, width, and thickness of the porous film before and after being baked at 300° C.

In following Examples, the peeling strength of the copper clad laminate was tested according to ASTM D1876. The solder resistance of the copper clad laminate was tested by dipping the copper clad laminate into the tin solder bath at 260° C. for 10 seconds and 30 seconds, respectively, to check any deformation occurred in the copper clad laminate to evaluate its solder resistance (Referring to Japan Patent No. JP4912021B2). The dielectric constant and the dissipation factor at 10 GHz of the copper clad laminate were measured according to ASTM D2520.

### Example 1 (Preparing the Polyamic Acid Having Side Hydroxyl Reactive Functional Groups)

DMB (0.49 parts by mole), ODA (0.49 parts by mole), and 6FAP (0.02 parts by mole) were added into a reactor. The mixture was stirred with 1-Methyl-2-pyrrolidone (NMP) at room temperature until all the monomers were completely dissolved. Subsequently, BPDA (0.8 parts by mole) and PMDA (0.2 parts by mole) were added into the reactor to be stirred overnight to obtain a polyamic acid having side hydroxyl reactive functional groups. The solid content of the product was about 15%, and the solvent thereof was NMP. The polyamic acid had a chemical structure of

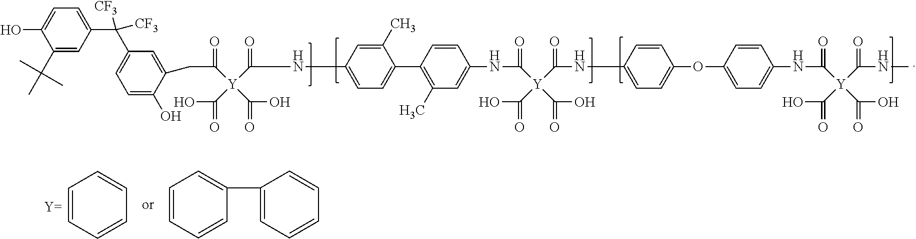

### (Preparing Side Chain Crosslinking Type Polyimide Porous Film)

The polyamic acid, multi-isocyanate Desmodur® N3300A (0.013 parts by mole, commercially available from Covestro AG), and NMP (500 g) were mixed and then heated to 80° C. to 100° C. to react for 3 hours. Subsequently, acetic anhydride (8 parts by mole) and pyridine (8 parts by mole) were quickly and continuously added to the reactor to obtain a sol, which was stirred for 5 minutes until completely mixed. The mixture was poured into a mold and stood at room temperature overnight. The gel sample was then taken from the mold, and the solvent of the gel sample was sequentially replaced by co-solvent (the mixture of NMP and acetone). During the solvent replacement, the co-solvent was gradually changed from 25% acetone to 100% acetone. After completing the solvent replacement, the gel sample was transferred to a sealed pressure vessel. The vessel was heated to 40° C., and 1200 psi of CO₂ was simultaneously introduced. Thereafter, the mixture of CO₂ and acetone was periodically and slowly exhausted from the vessel until all the acetone solvent was removed. The pressure of the vessel was then reduced to the atmospheric pressure, and a side chain crosslinking type polyimide aerogel substrate (i.e. porous film) prepared by the supercritical CO₂ drying method was obtained. The porous film had a density of 0.17 g/cm³, a porosity of 92.8%, an average pore size of 500 nm to 2000 nm, a thermal decomposition temperature (T_{d} 5%) of 503° C., a coefficient of thermal expansion of 29 ppm/° C., a compressive modulus of 22.5 MPa, a compressive stress at 10% strain of 0.97 MPa, a dielectric constant of 1.375 and a dissipation factor of 0.0135 at 10 GHz, and a volume contraction ratio at 300° C. for 2 hours of 15%.

### Example 2 (Preparing Side Chain Crosslinking Type Polyimide Porous Film)

Similar to Example 1, and the difference in Example 2 was after completing the solvent replacement, the acetone solvent was evaporated at room temperature under air circulation. The sample was then dried in an oven at 80° C. for 2 hours, and a side chain crosslinking type polyimide aerogel substrate (i.e. porous film) prepared by the ambient pressure drying method was obtained. The porous film had a density of 0.23 g/cm³, a porosity of 91.4%, an average pore size of 500 nm to 2000 nm, a thermal decomposition temperature (T_{d} 5%) of 506° C., a coefficient of thermal expansion of 30 ppm/° C., a compressive modulus of 19.2 MPa, a compressive stress at 10% strain of 1.14 MPa, a dielectric constant of 1.395 and a dissipation factor of 0.0095 at 10 GHz, and a volume contraction ratio at 300° C. for 2 hours of 14%.

### Comparative Example 1 (Preparing the Polyamic Acid without Side Hydroxyl Reactive Functional Group)

DMB (0.54 parts by mole) and ODA (0.54 parts by mole) were added into a reactor. The mixture was stirred with NMP at room temperature until all the monomers were completely dissolved. Subsequently, BPDA (0.8 parts by mole) and PMDA (0.2 parts by mole) were added into the reactor to be stirred overnight to obtain a polyamic acid without side hydroxyl reactive functional group. The solid content of the product was about 15%, and the solvent thereof was NMP.

### (Preparing Backbone Terminal Crosslinking Type Polyimide Porous Film)

The polyamic acid, multi-isocyanate Desmodur® N3300A (0.053 parts by mole), and NMP (500 g) were mixed. Subsequently, acetic anhydride (8 parts by mole) and pyridine (8 parts by mole) were quickly and continuously added to the reactor to obtain a sol, which was stirred for 5 minutes until completely mixed. The mixture was poured into a mold and stood at room temperature overnight. The gel sample was then taken from the mold, and the solvent of the gel sample was sequentially replaced by co-solvent (the mixture of NMP and acetone). During the solvent replacement, the co-solvent was gradually changed from 25% acetone to 100% acetone. After completing the solvent replacement, the gel sample was transferred to a sealed pressure vessel. The vessel was heated to 40° C., and 1200 psi of CO₂ was simultaneously introduced. Thereafter, the mixture of CO₂ and acetone was periodically and slowly exhausted from the vessel until all the acetone solvent was removed. The pressure of the vessel was then reduced to the atmospheric pressure, and a backbone terminal crosslinking type polyimide aerogel substrate (i.e. porous film) prepared by the supercritical CO₂ drying method was obtained. The porous film had a density of 0.20 g/cm³, a porosity of 91.9%, an average pore size of 50 nm to 300 nm, a thermal decomposition temperature (T_{d} 5%) of 500° C., a compressive modulus of 11.7 MPa, a compressive stress at 10% strain of 0.76 MPa, a dielectric constant of 1.450 and a dissipation factor of 0.0164 at 10 GHz, and a volume contraction ratio at 300° C. for 2 hours of 90%. The porous film was contracted and deformed, and the pores collapsed when heated, such that its coefficient of thermal expansion could not be measured.

### Comparative Example 2 (Preparing Backbone Terminal Crosslinking Type Polyimide Porous Film)

Similar to Comparative Example 1, and the difference in Comparative Example 2 was after completing the solvent replacement, the acetone solvent was evaporated at room temperature under air circulation. The sample was then dried in an oven at 80° C. for 2 hours. The pores collapsed during drying the sample, and the PI porous film could not be prepared. The dried sample had a density of 1.33 g/cm³.

### Example 3 (Preparing the Polyamic Acid Having Side Hydroxyl Reactive Functional Groups)

2,2′-Bis(trifluoromethyl) benzidine (TFMB, 0.7 parts by mole), 2,2-bis[4-(4-aminophenoxy)phenyl]propane (BAPP, 0.29 parts by mole), and 6FAP (0.01 parts by mole) were added into a reactor. The mixture was stirred with NMP at room temperature until all the monomers were completely dissolved. Subsequently, 4,4′-oxydiphthalic anhydride (ODPA, 0.7 parts by mole) and benzophenone-3,3′,4, 4′-tetracarboxylic dianhydride (BTDA, 0.3 parts by mole) were added into the reactor to be stirred overnight to obtain a polyamic acid having side hydroxyl reactive functional groups. The solid content of the product was about 15%, and the solvent thereof was NMP.

### (Preparing Side Chain Crosslinking Type Polyimide Porous Film)

The polyamic acid, Desmodur® N3300A (0.007 parts by mole), and NMP (500 g) were mixed and then heated to 80° C. to 100° C. to react for 3 hours. Subsequently, acetic anhydride (8 parts by mole) and pyridine (8 parts by mole) were quickly and continuously added to the reactor to obtain a sol, which was stirred for 5 minutes until completely mixed. The mixture was poured into a mold and stood at room temperature overnight. The gel sample was then taken from the mold, and the solvent of the gel sample was sequentially replaced by co-solvent (the mixture of NMP and acetone). During the solvent replacement, the co-solvent was gradually changed from 25% acetone to 100% acetone. After completing the solvent replacement, the acetone solvent was evaporated at room temperature under air circulation. The sample was then dried in an oven at 80° C. for 2 hours, and a side chain crosslinking type polyimide aerogel substrate (i.e. porous film) prepared by the ambient pressure drying method was obtained. The porous film had a density of 0.23 g/cm³, a porosity of 91.1%, an average pore size of 500 nm to 2000 nm, a thermal decomposition temperature (T_{d} 5%) of 510° C., a coefficient of thermal expansion of 37 ppm/° C., a compressive modulus of 17.6 MPa, a compressive stress at 10% strain of 1.39 MPa, a dielectric constant of 1.354 and a dissipation factor of 0.0096 at 10 GHz, and a volume contraction ratio at 300° C. for 2 hours of 12%.

### Example 4 (Preparing the Polyamic Acid Having Side Hydroxyl Reactive Functional Groups)

4,4′-Bis(4-aminophenoxy) biphenyl (BAPB, 0.5 parts by mole), p-phenylenediamine (PPD, 0.4 parts by mole), and 6FAP (0.1 parts by mole) were added into a reactor. The mixture was stirred with NMP at room temperature until all the monomers were completely dissolved. Subsequently, 4,4′-(hexafluoroisopropylidene) diphthalic anhydride (6FDA, 0.6 parts by mole) and BTDA (0.4 parts by mole) were added into the reactor to be stirred overnight to obtain a polyamic acid having side hydroxyl reactive functional groups. The solid content of the product was about 15%, and the solvent thereof was NMP.

### (Preparing Side Chain Crosslinking Type Polyimide Porous Film)

The polyamic acid, Desmodur® N3300A (0.067 parts by mole), and NMP (500 g) were mixed and then heated to 80° C. to 100° C. to react for 3 hours. Subsequently, acetic anhydride (8 parts by mole) and pyridine (8 parts by mole) were quickly and continuously added to the reactor to obtain a sol, which was stirred for 5 minutes until completely mixed. The mixture was poured into a mold and stood at room temperature overnight. The gel sample was then taken from the mold, and the solvent of the gel sample was sequentially replaced by co-solvent (the mixture of NMP and acetone). During the solvent replacement, the co-solvent was gradually changed from 25% acetone to 100% acetone. After completing the solvent replacement, the acetone solvent was evaporated at room temperature under air circulation. The sample was then dried in an oven at 80° C. for 2 hours, and a side chain crosslinking type polyimide aerogel substrate (i.e. porous film) prepared by the ambient pressure drying method was obtained. The porous film had a density of 0.22 g/cm³, a porosity of 91.8%, an average pore size of 500 nm to 2000 nm, a thermal decomposition temperature (T_{d} 5%) of 521° C., a coefficient of thermal expansion of 34 ppm/° C., a compressive modulus of 23.9 MPa, a compressive stress at 10% strain of 1.22 MPa, a dielectric constant of 1.328 and a dissipation factor of 0.0101 at 10 GHz, and a volume contraction ratio at 300° C. for 2 hours of 6%.

### Example 5 (Preparing the Polyamic Acid Having Side Hydroxyl Reactive Functional Groups)

9,9′-Bis(4-aminophenyl)fluorene (FDA, 0.5 parts by mole), 1,4-bis(4-aminophenoxy)benzene (TPE-Q, 0.3 parts by mole), and 6FAP (0.2 parts by mole) were added into a reactor. The mixture was stirred with NMP at room temperature until all the monomers were completely dissolved. Subsequently, 4,4′-(4,4′-isopropylidenediphenoxy) diphthalic anhydride (BPADA, 0.2 parts by mole) and BPDA (0.8 parts by mole) were added into the reactor to be stirred overnight to obtain a polyamic acid having side hydroxyl reactive functional groups. The solid content of the product was about 15%, and the solvent thereof was NMP.

### (Preparing Side Chain Crosslinking Type Polyimide Porous Film)

The polyamic acid, Desmodur® N3300A (0.133 parts by mole), and NMP (500 g) were mixed and then heated to 80° C. to 100° C. to react for 3 hours. Subsequently, acetic anhydride (8 parts by mole) and pyridine (8 parts by mole) were quickly and continuously added to the reactor to obtain a sol, which was stirred for 5 minutes until completely mixed. The mixture was poured into a mold and stood at room temperature overnight. The gel sample was then taken from the mold, and the solvent of the gel sample was sequentially replaced by co-solvent (the mixture of NMP and acetone). During the solvent replacement, the co-solvent was gradually changed from 25% acetone to 100% acetone. After completing the solvent replacement, the acetone solvent was evaporated at room temperature under air circulation. The sample was then dried in an oven at 80° C. for 2 hours, and a side chain crosslinking type polyimide aerogel substrate (i.e. porous film) prepared by the ambient pressure drying method was obtained. The porous film had a density of 0.26 g/cm³, a porosity of 90.6%, an average pore size of 600 nm to 2000 nm, a thermal decomposition temperature (T_{d} 5%) of 518° C., a coefficient of thermal expansion of 37 ppm/° C., a compressive modulus of 28.6 MPa, a compressive stress at 10% strain of 0.87 MPa, a dielectric constant of 1.345 and a dissipation factor of 0.0103 at 10 GHz, and a volume contraction ratio at 300° C. for 2 hours of 8%.

### Comparative Example 3 (Preparing the Polyamic Acid Having Side Hydroxyl Reactive Functional Groups)

ODA (0.496 parts by mole), DMB (0.496 parts by mole), and 6FAP (0.008 parts by mole) were added into a reactor. The mixture was stirred with NMP at room temperature until all the monomers were completely dissolved. Subsequently, BPDA (0.8 parts by mole) and PMDA (0.2 parts by mole) were added into the reactor to be stirred overnight to obtain a polyamic acid having side hydroxyl reactive functional groups. The solid content of the product was about 15%, and the solvent thereof was NMP.

### (Preparing Side Chain Crosslinking Type Polyimide Porous Film)

The polyamic acid, Desmodur® N3300A (0.005 parts by mole), and NMP (500 g) were mixed and then heated to 80° C. to 100° C. to react for 3 hours. Subsequently, acetic anhydride (8 parts by mole) and pyridine (8 parts by mole) were quickly and continuously added to the reactor to obtain a sol, which was stirred for 5 minutes until completely mixed. The mixture was poured into a mold and stood at room temperature overnight. The gel sample was then taken from the mold, and the solvent of the gel sample was sequentially replaced by co-solvent (the mixture of NMP and acetone). During the solvent replacement, the co-solvent was gradually changed from 25% acetone to 100% acetone. After completing the solvent replacement, the acetone solvent was evaporated at room temperature under air circulation. The sample was then dried in an oven at 80° C. for 2 hours, and a side chain crosslinking type polyimide aerogel substrate (i.e. porous film) prepared by the ambient pressure drying method was obtained. The porous film had a density of 0.23 g/cm³, a porosity of 91.4%, an average pore size of 500 nm to 1500 nm, a thermal decomposition temperature (T_{d} 5%) of 509° C., a coefficient of thermal expansion of 43 ppm/° C., a compressive modulus of 12.6 MPa, a compressive stress at 10% strain of 1.07 MPa, a dielectric constant of 1.383 and a dissipation factor of 0.0099 at 10 GHz, and a volume contraction ratio at 300° C. for 2 hours of 13%. As known from Comparative Example 3, when 6FAP amount (i.e. (a1) first diamine) was too low, the network density and the porous skeleton strength of the porous film would be insufficient. The porous film would easily expand and contract as the temperature changed, thereby increasing the coefficient of thermal expansion. The overly low porous skeleton strength would degrade the mechanical properties of the porous film.

### Comparative Example 4 (Preparing the Polyamic Acid Having Side Hydroxyl Reactive Functional Groups)

ODA (0.375 parts by mole), DMB (0.375 parts by mole), and 6FAP (0.25 parts by mole) were added into a reactor. The mixture was stirred with NMP at room temperature until all the monomers were completely dissolved. Subsequently, BPDA (0.8 parts by mole) and PMDA (0.2 parts by mole) were added into the reactor to be stirred overnight to obtain a polyamic acid having side hydroxyl reactive functional groups. The solid content of the product was about 15%, and the solvent thereof was NMP.

### (Preparing Side Chain Crosslinking Type Polyimide Porous Film)

The polyamic acid, Desmodur® N3300A (0.167 parts by mole), and NMP (500 g) were mixed and then heated to 80° C. to 100° C. to react for 3 hours. Subsequently, acetic anhydride (8 parts by mole) and pyridine (8 parts by mole) were quickly and continuously added to the reactor to obtain a sol, which was stirred for 5 minutes until completely mixed. The mixture was poured into a mold and stood at room temperature overnight. The gel sample was then taken from the mold, and the solvent of the gel sample was sequentially replaced by co-solvent (the mixture of NMP and acetone). During the solvent replacement, the co-solvent was gradually changed from 25% acetone to 100% acetone. After completing the solvent replacement, the acetone solvent was evaporated at room temperature under air circulation. The sample was then dried in an oven at 80° C. for 2 hours, and a side chain crosslinking type polyimide aerogel substrate (i.e. porous film) prepared by the ambient pressure drying method was obtained. The porous film had a density of 0.31 g/cm³, a porosity of 88.7%, an average pore size of 600 nm to 2700 nm, a thermal decomposition temperature (T_{d} 5%) of 472° C., a coefficient of thermal expansion of 33 ppm/° C., a compressive modulus of 30.8 MPa, a compressive stress at 10% strain of 0.58 MPa, a dielectric constant of 1.447 and a dissipation factor of 0.0211 at 10 GHz, and a volume contraction ratio at 300° C. for 2 hours of 10%. As known from Comparative Example 4, when 6FAP amount (i.e. (a1) first diamine) was too high, the network density of the porous film would be too high, thereby increasing the brittleness of the material and decreasing the porosity of the material. In addition, the overly high amount of bondings prone to high temperature cleavage would degrade the thermal resistance of the material.

### Example 6

Hydrogenated styrene based thermoplastic elastomer SEBS (S1611 commercially available from Japan Asahi Kasei Co., 100 g) was dissolved in toluene (500 g). 0.8 wt % of an initiator dicumyl peroxide (DCP) and 2.0 wt % of a crosslinking agent triallylisocyanurate (TAIC) were added to the toluene solution, and then stirred at 25° C. for 3 hours to be completely dissolved. The solution with a solid content of 17.8% was coated on a PET release film by a blade with a gap of 75 μm. The coating was baked dry in an oven at 110° C. for 1 hour to obtain an adhesive layer with a thickness of 15 μm. On the other hand, the solution with a solid content of 17.8% was coated on a PET release film by a blade with a gap of 150 μm. The coating was baked dry in an oven at 110° C. for 1 hour to obtain an adhesive layer with a thickness of 30 μm.

The mold height in Example 2 was adjusted to prepare the porous films having thicknesses of about 160 μm, 400 μm, and 730 μm, respectively. The adhesive layers having a thickness of 15 μm were attached to the top side and the bottom side of the porous film having a thickness of about 160 μm. The above tri-layered structure was interposed between two copper foils (commercially available from Furukawa Chemical, having a thickness of about 12 μm). The above structure was pressed under vacuum at 150° C. to form a copper clad laminate composed of multi-layered films. The composite structure of the copper clad laminate was sequentially copper foil, adhesive layer, porous film, adhesive layer, and copper foil from top to bottom. The copper clad laminate could pass the peeling strength test and the solder resistance test (e.g. in solder bath at 260° C. for 10 seconds and 30 seconds, respectively). The copper clad laminate had an adhesive strength of 16.9 N/cm, and a dielectric constant of 1.650 and a dissipation factor of 0.0063 at 10 GHz.

The adhesive layers having a thickness of 30 μm were attached to the top side and the bottom side of the porous film having a thickness of about 400 μm. The above tri-layered structure was interposed between two copper foils (commercially available from Furukawa Chemical, having a thickness of about 12 μm). The above structure was pressed under vacuum at 150° C. to form a copper clad laminate composed of multi-layered films. The composite structure of the copper clad laminate was sequentially copper foil, adhesive layer, porous film, adhesive layer, and copper foil from top to bottom. The copper clad laminate could pass the peeling strength test and the solder resistance test (e.g. in solder bath at 260° C. for 10 seconds and 30 seconds, respectively). The copper clad laminate had an adhesive strength of 17.7 N/cm, and a dielectric constant of 1.517 and a dissipation factor of 0.0049 at 10 GHz.

The adhesive layers having a thickness of 30 μm were attached to the top side and the bottom side of the porous film having a thickness of about 730 μm. The above tri-layered structure was interposed between two copper foils (commercially available from Furukawa Chemical, having a thickness of about 12 μm). The above structure was pressed under vacuum at 150° C. to form a copper clad laminate composed of multi-layered films. The composite structure of the copper clad laminate was sequentially copper foil, adhesive layer, porous film, adhesive layer, and copper foil from top to bottom. The copper clad laminate could pass the peeling strength test and the solder resistance test (e.g. in solder bath at 260° C. for 10 seconds and 30 seconds, respectively). The copper clad laminate had an adhesive strength of 16.3 N/cm, and a dielectric constant of 1.516 and a dissipation factor of 0.0047 at 10 GHz.

### Comparative Example 5

The adhesive layers having a thickness of 30 μm in Example 6 were attached to the top side and the bottom side of a polyethylene non-woven fabric (CLAF commercially available from ENEOS techno materials Co., having a thickness of 220 μm). The above tri-layered structure was interposed between two copper foils (commercially available from Furukawa Chemical, having a thickness of about 12 μm). The above structure was pressed under vacuum at 150° C. to form a copper clad laminate composed of multi-layered films. The composite structure of the copper clad laminate was sequentially copper foil, adhesive layer, polyethylene non-woven fabric, adhesive layer, and copper foil from top to bottom. The copper clad laminate could pass the peeling strength test. The copper clad laminate had an adhesive strength of 13.5 N/cm, and a dielectric constant of 1.656 and a dissipation factor of 0.0008 at 10 GHz. However, the copper clad laminate could not pass the solder resistance test (e.g. in solder bath at 260° C. for 10 seconds and 30 seconds, respectively). The copper clad laminate could not withstand the general printed circuit board process (e.g. soldering), and melted by the soldering process to lose the dielectric properties.

It will be apparent to those skilled in the art that various modifications and variations can be made to the disclosed methods and materials. It is intended that the specification and examples be considered as exemplary only, with the true scope of the disclosure being indicated by the following claims and their equivalents.

What is claimed is:

1. A porous film, being formed by reacting polyamic acid and multi-isocyanate, and the polyamic acid is formed by reacting
1 to 20 parts by mole of (a1) first diamine having a hydroxyl group;
80 to 99 parts by mole of (a2) second diamine without any hydroxyl group; and
100 parts by mole of (b) dianhydride,
wherein the multi-isocyanate and (b) dianhydride have a molar ratio of 0.25:100 to 20:100, and
wherein the porous film has an average pore size of 500 nm to 2000 nm.

2. The porous film as claimed in claim 1, wherein (a1) first diamine has a chemical structure of H₂N—Ar¹—NH₂, wherein Ar¹ is 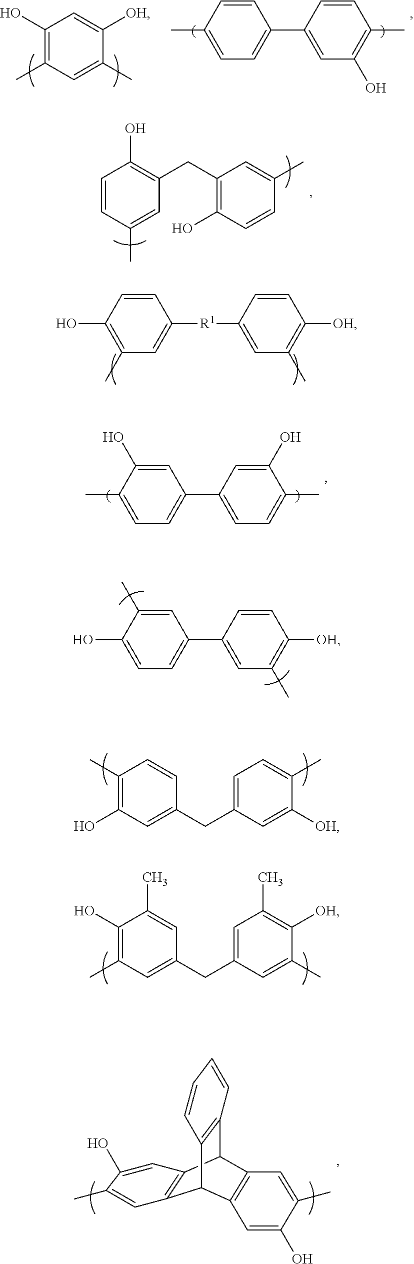 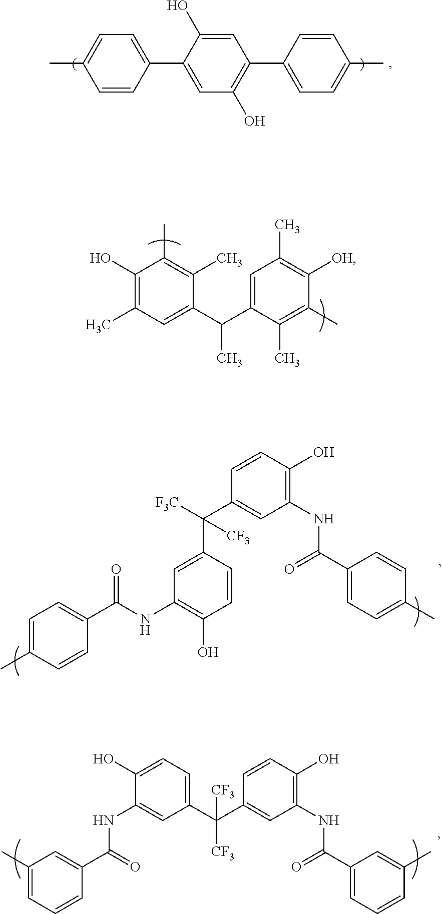
or a combination thereof,
wherein R¹ is —SO₂—, —C(CH₃)₂—, or —C(CF₃)₂—.

3. The porous film as claimed in claim 1, wherein (a2) second diamine has a chemical structure of H₂N—Ar²—NH₂, wherein Ar² is —(CH₂)ₙ—, 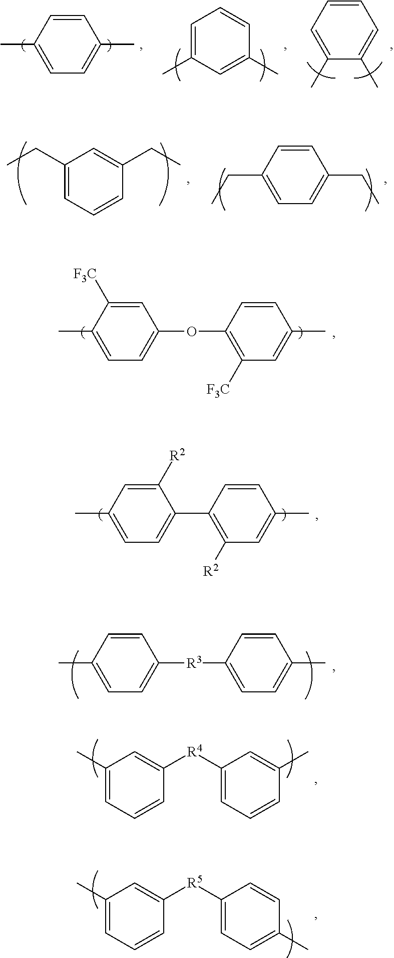
or a combination thereof,
wherein n=1 to 10,
wherein R² is —H, —CH₃, —CF₃, or —OCH₃,
wherein R³ is —O—, —S—, —CH₂—, —CO—, —SO₂—, —CONH—, —C(CH₃)₂—, —C(CF₃)₂—, —O(CH₂)₃O—, —O(CH₂)₄O—, 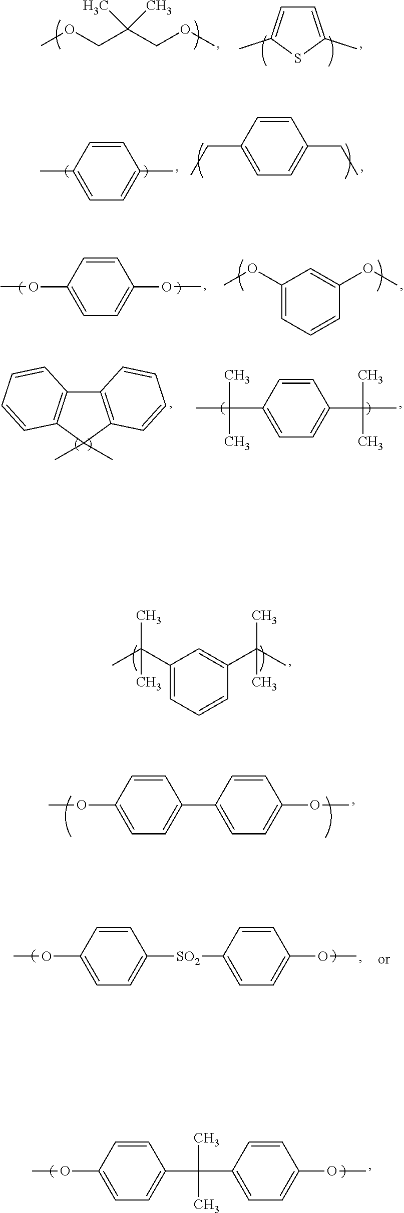
wherein R⁴ is —O—, —CH₂—, —CO—, —SO₂—, 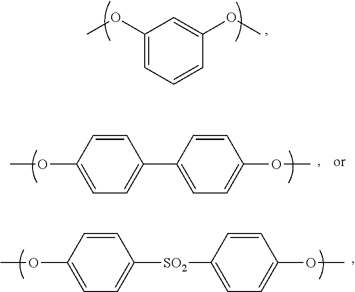
and
wherein R⁵ is —O—, —CH₂—, —CONH—,

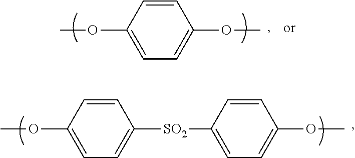

4. The porous film as claimed in claim 1, wherein (b) dianhydride has a chemical structure of 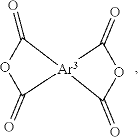
wherein Ar³ is 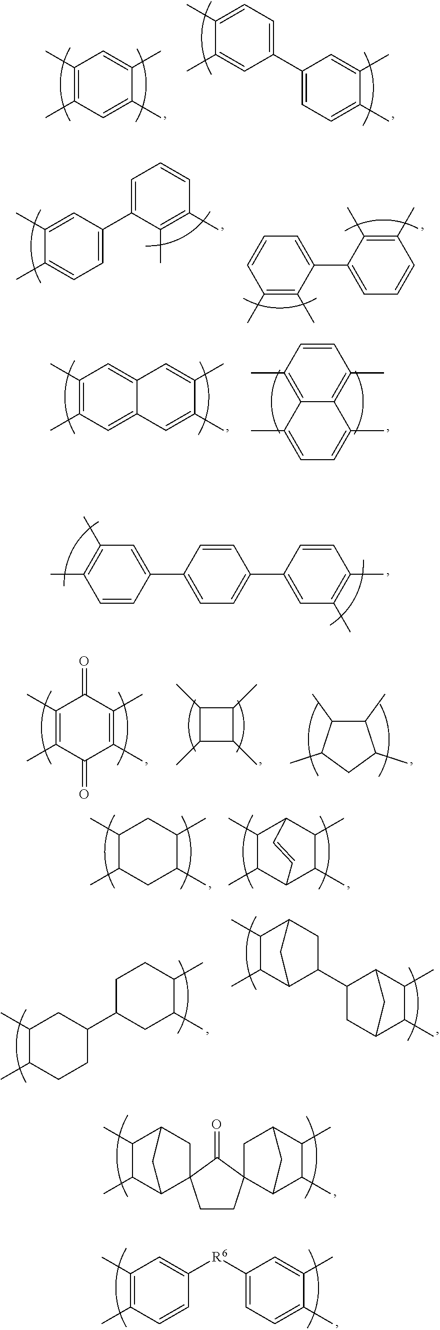
or a combination thereof,
wherein R⁶ is —O—, —S—, —C≡C—, —CO—, —COO—, —SO₂—, —C(CF₃)₂—, —COO(CH₂)₂OCO—,

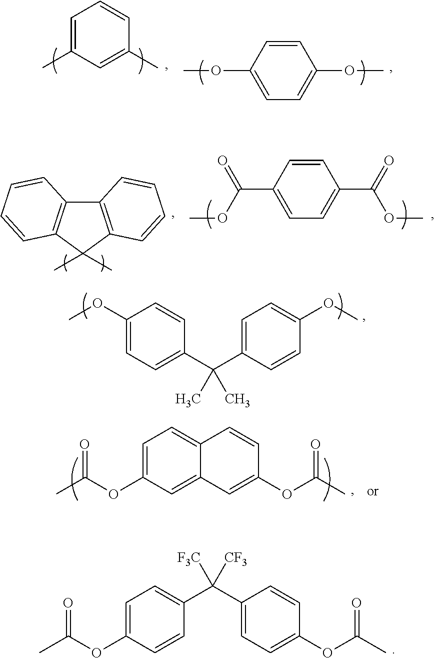

5. The porous film as claimed in claim 1, wherein the multi-isocyanate is diisocyanate, triisocyanate, tetraisocyanate, or a combination thereof,
wherein the diisocyanate has a chemical structure of OCN—R⁷—NCO, wherein R⁷ is —(CH₂)₅—, —(CH₂)₆—, 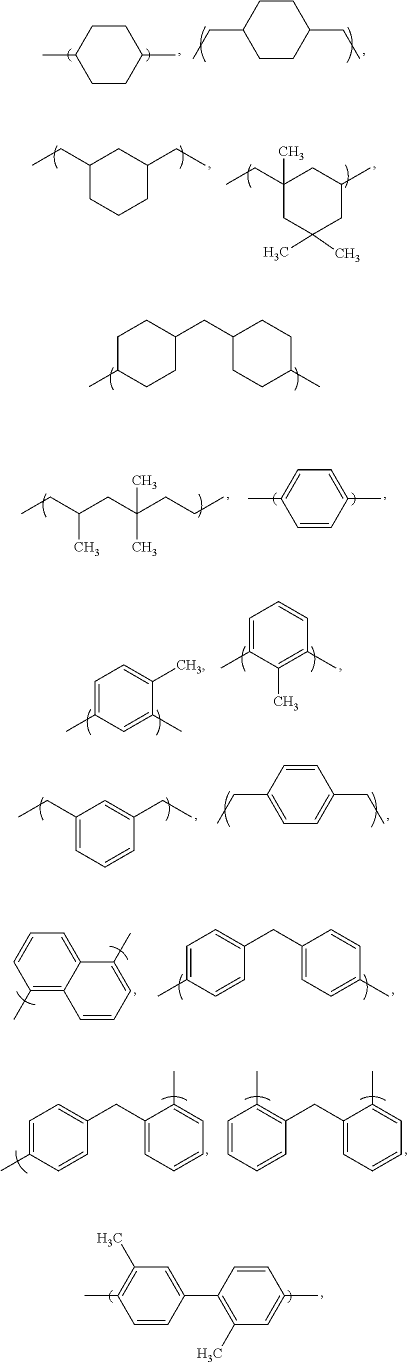
or a combination thereof;
wherein the triisocyanate has a chemical structure of 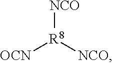
wherein R⁸ is 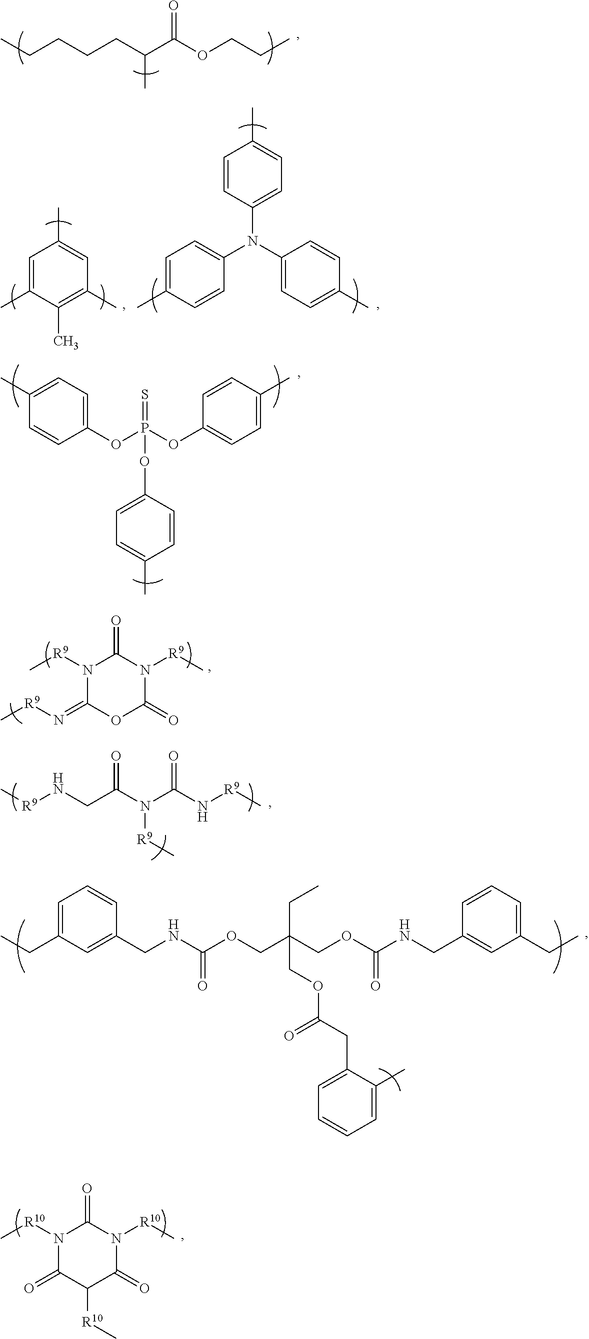
or a combination thereof,
wherein R⁹ is —(CH₂)₆—,
each of R¹⁰ is independently —(CH₂)₆—, 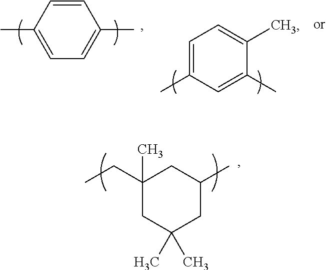
wherein the tetraisocyanate is tetraisocyanatosilane, 4,4′-benzylidenebis(6-methyl-m-phenylene) tetraisocyanate, or a combination thereof.

6. The porous film as claimed in claim 1, having a dielectric constant of <1.4 and a dissipation factor of <0.02 at 10 GHz.

7. A copper clad laminate, comprising:
the porous film as claimed in claim 1 interposed between two copper foils; and
two thermosetting ethylene copolymer resin layers being respectively between the porous film and the copper foils.

8. The copper clad laminate as claimed in claim 7, wherein the thermosetting ethylene copolymer resin layers comprise di-block or tri-block hydrogenated styrene elastomer resin.

9. The copper clad laminate as claimed in claim 7, wherein the thermosetting ethylene copolymer resin layers comprise di-block or tri-block hydrogenated (styrene-isoprene) copolymer.

10. The copper clad laminate as claimed in claim 7, having a dielectric constant of <2.0 and a dissipation factor of <0.01 at 10 GHz.
